(19) United States
(12) Patent Application Publication
(10) Pub. No.: US 2025/0239522 A1
(43) Pub. Date: Jul. 24, 2025

(54) INTEGRATED CIRCUIT (IC) PACKAGE WITH EMBEDDED POWER MANAGEMENT INTEGRATED CIRCUIT (PMIC)

(71) Applicant: QUALCOMM Incorporated, San Diego, CA (US)

(72) Inventors: Xia LI, San Diego, CA (US); Bin YANG, San Diego, CA (US); Giridhar NALLAPATI, San Diego, CA (US)

(21) Appl. No.: 18/420,231

(22) Filed: Jan. 23, 2024

(51) Int. Cl. H01L 23/528; H01L 23/00; H01L 23/367; H01L 23/498; H01L 23/522; H01L 25/00; H01L 25/065

(52) U.S. Cl. CPC H01L 23/5286; H01L 23/367; H01L 23/49838; H01L 23/5223; H01L 24/16; H01L 25/0657; H01L 25/50; H01L 2224/16145; H01L 2224/16225; H01L 2225/06517; H01L 2225/0652; H01L 2924/1431; H01L 2924/1436

(57) ABSTRACT

In an aspect, an integrated circuit (IC) package includes a package substrate including at least a first power node and a second power node; an interposer on the package substrate; and an IC die on the interposer. The interposer may include a dielectric layer and a power management integrated circuit (PMIC) embedded in the dielectric layer, where the PMIC includes a third power node and a fourth power node, and the third power node may be electrically coupled to the first power node. The IC die may include a fifth power node and a sixth power node, where the fifth power node may be electrically coupled to the fourth power node, and the sixth power node may be electrically coupled to the second power node.

### TECHNICAL FIELD

The present disclosure generally relates to an integrated circuit (IC) package, and, more particularly, to an IC package that includes an interposer with an embedded power management integrated circuit (PMIC).

### BACKGROUND

IC technology has achieved great strides in advancing computing power through miniaturization of electronic components. An IC chip or an IC die may include a set of circuits integrated thereon. In some implementations, an IC device may be formed by incorporating and protecting one or more IC dies in an IC package, where various power and signal nodes of the one or more IC dies can be electrically coupled to respective conductive terminals of the IC package via electrical paths formed in one or more package substrates of the IC package.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and/or other communications), and the like.

For example, an interposer may be used in an IC package, where one or more IC dies may be mounted on the interposer, and the interposer may be further mounted on another IC die, based on a three-dimensional IC (3DIC) packaging scheme. The IC package may be further mounted on a circuit board (e.g., a printed circuit board, or known as a PCB). In some examples, a power management integrated circuit (PMIC) (e.g., in the form of another IC package) may be mounted on the PCB and configured to manage one or more power distribution networks (PDNs) for supplying power to the IC dies in the IC package.

In some examples, the PMIC is configured to receive an external power supply at a higher voltage level (e.g., 5˜12 volts (V)) to an internal supply voltage at a lower voltage level (0.7˜1.0 V) for energizing the IC die(s) in the IC package (e.g., providing electrical energy for operating the IC die(s) based on the voltage difference between the higher voltage level and the lower voltage level). However, the conductive path from the PMIC to the IC die(s) that is energized based on the internal voltage supply may cause a potential drop as the operation current (e.g., denoted “I”) passing through the resistance (e.g., denoted “R”) of the conductive path (such potential drop is also referred to as an IR drop) that may be quite significant compared with the voltage level of the internal supply voltage.

Accordingly, there may be a need to arrange an IC die and the corresponding PMIC in order to reduce the IR drop between the IC die and the PMIC.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an integrated circuit (IC) package includes a package substrate including at least a first power node and a second power node; an interposer on the package substrate, the interposer including: a dielectric layer; and a power management integrated circuit (PMIC) embedded in the dielectric layer, the PMIC including a third power node and a fourth power node, and the third power node being electrically coupled to the first power node; and an IC die on the interposer, the IC die including a fifth power node and a sixth power node, the fifth power node being electrically coupled to the fourth power node, and the sixth power node being electrically coupled to the second power node, wherein: the first power node and the third power node are configured to carry a first supply voltage having a first voltage level, the fourth power node and the fifth power node are configured to carry a second supply voltage having a second voltage level different from the first voltage level, the second power node and the sixth power node are configured to carry a third supply voltage having a ground voltage level or a third voltage level different from the first voltage level and the second voltage level, and the PMIC is configured to receive at the third power node the first supply voltage, and output at the fourth power node the second supply voltage.

In an aspect, a method of manufacturing an integrated circuit (IC) package includes disposing an interposer on a package substrate, the package substrate including at least a first power node and a second power node, and the interposer including: a dielectric layer; and a power management integrated circuit (PMIC) embedded in the dielectric layer, the PMIC including a third power node and a fourth power node, and the third power node being electrically coupled to the first power node; and disposing an IC die on the interposer, the IC die including a fifth power node and a sixth power node, the fifth power node being electrically coupled to the fourth power node, and the sixth power node being electrically coupled to the second power node, wherein: the first power node and the third power node are configured to carry a first supply voltage having a first voltage level, the fourth power node and the fifth power node are configured to carry a second supply voltage having a second voltage level different from the first voltage level, the second power node and the sixth power node are configured to carry a third supply voltage having a ground voltage level or a third voltage level different from the first voltage level and the second voltage level, and the PMIC is configured to receive at the third power node the first supply voltage, and output at the fourth power node the second supply voltage.

In an aspect, an electronic device includes an integrated circuit (IC) package that comprises: a package substrate including at least a first power node and a second power node; an interposer on the package substrate, the interposer including: a dielectric layer; and a power management integrated circuit (PMIC) embedded in the dielectric layer, the PMIC including a third power node and a fourth power node, and the third power node being electrically coupled to the first power node; and an IC die on the interposer, the IC die including, a fifth power node and a sixth power node, the fifth power node being electrically coupled to the fourth power node, and the sixth power node being electrically coupled to the second power node, wherein: the first power node and the third power node are configured to carry a first supply voltage having a first voltage level, the fourth power node and the fifth power node are configured to carry a second supply voltage having a second voltage level different from the first voltage level, the second power node and the sixth power node are configured to carry a third supply voltage having a ground voltage level or a third voltage level different from the first voltage level and the second voltage level, and the PMIC is configured to receive at the third power node the first supply voltage, and output at the fourth power node the second supply voltage.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A is a cross-sectional view of a portion of a first circuit board assembly example, according to aspects of the disclosure.

FIG. 1B is a cross-sectional view of a portion of a second circuit board assembly example, according to aspects of the disclosure.

FIG. 2 is a cross-sectional view of a portion of an integrated circuit (IC) die, according to aspects of the disclosure.

FIG. 3A is a cross-sectional view of a first IC package example, according to aspects of the disclosure.

FIG. 3B is a cross-sectional view of a second IC package example, according to aspects of the disclosure.

FIGS. 4A-4G illustrate structures at various stages of manufacturing an IC package based on a first manufacturing process example, according to aspects of the disclosure.

FIGS. 5A-5H illustrate structures at various stages of manufacturing an IC package based on a second manufacturing process example, according to aspects of the disclosure.

FIG. 6 illustrates a method for manufacturing an IC package, according to aspects of the disclosure.

FIG. 7 illustrates a mobile device, according to aspects of the disclosure.

FIG. 8 illustrates various electronic devices that may incorporate IC devices being put into the IC packages as described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, and the like indicate that the examples provided are not intended to be limited to the precise numerical values or geometric shapes and include normal variations due to, manufacturing tolerances and variations, material variations, and other design considerations.

As noted in the foregoing, various aspects relate generally to manufacturing an integrated circuit (IC) package that includes an interposer with an embedded power management integrated circuit (PMIC). The IR drop (“I” denoting current and “R” denoting resistance) regarding the supply voltages may be reduced, which may improve the computational performance and reduce the power consumption of an IC die (e.g., an IC die with multiple processing cores).

Particular aspects of the subject matter described in this disclosure can be implemented to realize one or more of the following potential advantages. In some aspects, by relying upon the PMIC to provide the functionality of the power switch for an IC die in the IC package, the IR drop caused by the supply voltage coupled through a metallization portion of the IC die up and down to reach a power switch of the IC die and then back to a power distribution network (PDN) of the IC die may be reduced or eliminated. Also, by having the PMIC inside the IC package, the IR drop caused by the supply voltage coupled through the conductive path of a PCB may be eliminated. In some aspects, the capacitive device may increase the stability of the supply voltages. In some aspects, the IC package according to the present application with reduced IR drop may improve the performance of an IC die (e.g., with multiple processing cores) by reducing an internal supply voltage, increasing an operation frequency, or both.

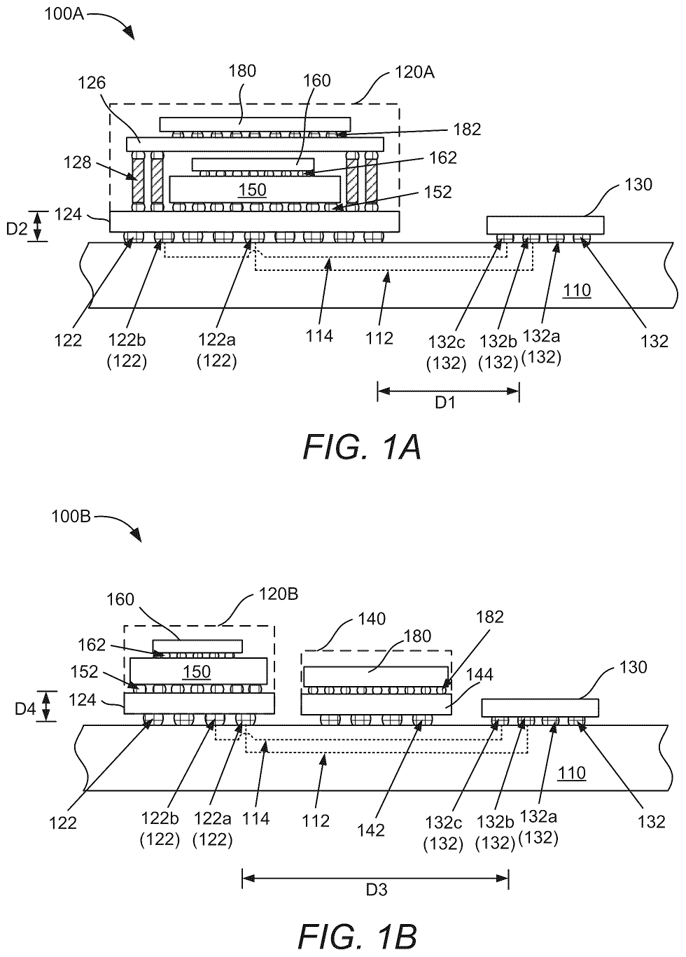

FIG. 1A is a cross-sectional view of a portion of a first circuit board assembly example 100A, according to aspects of the disclosure. In some aspects, FIG. 1A is a simplified cross-sectional view of the first circuit board assembly example 100A, and certain details and components of the first circuit board assembly example 100A may be simplified or omitted in FIG. 1A.

As shown in FIG. 1A, the first circuit board assembly example 100A may include a PCB 110, an IC package 120A mounted on the PCB 110, and a PMIC (in the form of another IC package) 130 mounted on the PCB 110. In some aspects, the PCB 110 may include layers of conductive patterns formed therein (not shown). In some aspects, the IC package 120A may be mounted on the PCB 110 through terminal structures 122 (e.g., solder bumps based on a controlled collapse of chip connection (C4) mounting method, also referred to as C4 bumps). In some aspects, the PMIC 130 may be mounted on the PCB 110 through terminal structures 132 (e.g., C4 bumps).

In some aspects, the IC package 120A may include a first package substrate 124, a first IC die 150 mounted on the first package substrate 124 through terminal structures 152 (e.g., solder bumps or copper pillar bumps), a second IC die 160 mounted on the first IC die 150 through terminal structures 162 (e.g., solder bumps or copper pillar bumps), a second package substrate 126 mounted on the first package substrate 124 through terminal structures 128 (e.g., solder bumps or copper pillar bumps together with conductive pillars), and a third IC die 180 mounted on the second package substrate 126 through terminal structures 182 (e.g., solder bumps or copper pillar bumps). In some aspects, the first IC die 150 may be a logic IC die, the second IC die may be a cache memory (e.g., a last level cache (LLC) dynamic random access memory (DRAM)) die, and the third IC die 180 may be a DRAM die.

In some aspects, the PMIC 130 may include a first power node (e.g., corresponding to the terminal structure 132a of the terminal structures 132) configured to carry a first supply voltage, a second power node (e.g., corresponding to the terminal structure 132b of the terminal structures 132) configured to carry a second supply voltage, and a third power node (e.g., corresponding to the terminal structure 132c of the terminal structures 132) configured to carry a third supply voltage. In some aspects, the first supply voltage may have a first voltage level, the second supply voltage may have a second voltage level different from the first voltage level, and the third supply voltage may have a ground voltage level or a third voltage level different from the first voltage level and the second voltage level. In some aspects, the third supply voltage may be the ground voltage level, the second voltage level may be greater than the ground voltage level and may range from 0.7 V to 1.0 V. In some aspects, the first voltage level may be greater than the second voltage level and may range from 5 V to 12 V.

In some aspects, the PMIC 130 may be configured to receive the first supply voltage at the terminal structure 132a, and output the second supply voltage at the terminal structure 132b to the terminal structure 122a of the terminal structures 122 of the IC package 120A through a conductive path 112 formed by various conductive patterns in the PCB 110. In some aspects, the PMIC 130 may be configured to carry the third supply voltage at the terminal structure 132c, which is also electrically shared by the terminal structure 122b of the terminal structures 122 of the IC package 120A through a conductive path 114 formed by various conductive patterns in the PCB 110. In some aspects, the IC dies 150, 160, and 180 may be energized (e.g., the electrical energy for operating the IC dies being provided) based on a voltage difference between a power node carrying the second supply voltage (from the terminal structure 122a and through at least the corresponding conductive patterns of the first package substrate 124) and a power node carrying the third supply voltage (from the terminal structure 122b and through at least the corresponding conductive patterns of the first package substrate 124).

In some aspects, a minimum distance D1 of the conductive paths 112 and 114 between the IC package 120A and the PMIC 130 may be at least 10 millimeters (mm) to 100 mm. In some aspects, a minimum distance D2 of a conductive path through one of the terminal structures 122 and the first package substrate 124 may be at least 500 micrometers (μm) to 1000 μm. In some aspects, a conductive path from the PMIC 130 to the first IC die 150 may have a length of at least the summation of the distances D1 and D2, which may cause significant IR drop and parasitic inductance along the conductive path.

FIG. 1B is a cross-sectional view of a portion of a second circuit board assembly example 100B, according to aspects of the disclosure. In some aspects, FIG. 1B is a simplified cross-sectional view of the second circuit board assembly example 100B, and certain details and components of the second circuit board assembly example 100B may be simplified or omitted in FIG. 1B. In some aspects, the components in FIG. 1B that are the same or similar to those in FIG. 1A are given the same reference numbers, and detailed description thereof may be omitted.

As shown in FIG. 1B, the second circuit board assembly example 100B may include a PCB 110, a first IC package 120B mounted on the PCB 110, a second IC package 140 mounted on the PCB 110, and a PMIC (in the form of another IC package) 130 mounted on the PCB 110. In some aspects, the first IC package 120B may be mounted on the PCB 110 through terminal structures 122 (e.g., C4 bumps). In some aspects, the PMIC 130 may be mounted on the PCB 110 through terminal structures 132 (e.g., C4 bumps). In some aspects, the second IC package 140 may be mounted on the PCB 110 through terminal structures 142 (e.g., C4 bumps).

In some aspects, the first IC package 120B may include a first package substrate 124, a first IC die 150 mounted on the first package substrate 124 through terminal structures 152 (e.g., solder bumps or copper pillar bumps), and a second IC die 160 mounted on the first IC die 150 through terminal structures 162 (e.g., solder bumps or copper pillar bumps). In some aspects, the second IC package 140 may include a second package substrate 144 mounted on the first package substrate 124 through terminal structures 142, and a third IC die 180 mounted on the second package substrate 144 through terminal structures 182 (e.g., solder bumps or copper pillar bumps). In some aspects, the first IC die 150 may be a logic IC die, the second IC die may be a cache memory (e.g., an LLC DRAM) die, and the third IC die 180 may be a DRAM die.

In some aspects, the PMIC 130 may include a first power node (e.g., corresponding to the terminal structure 132a) configured to carry a first supply voltage, a second power node (e.g., corresponding to the terminal structure 132b) configured to carry a second supply voltage, and a third power node (e.g., corresponding to the terminal structure 132c) configured to carry a third supply voltage, as illustrated in FIG. 1A. In some aspects, the PMIC 130 may be configured to receive the first supply voltage at the terminal structure 132a, and output the second supply voltage at the terminal structure 132b to the terminal structure 122a of the terminal structures 122 of the first IC package 120B through a conductive path 112 formed by various conductive patterns in the PCB 110. In some aspects, the PMIC 130 may be configured to carry the third supply voltage at the terminal structure 132c, which is also electrically shared by the terminal structure 122b of the terminal structures 122 of the first IC package 120B through a conductive path 114 formed by various conductive patterns in the PCB 110. In some aspects, the IC dies 150 and 160 may be energized based on a voltage difference between a power node carrying the second supply voltage (from the terminal structure 122a and through at least the corresponding conductive patterns of the first package substrate 124) and a power node carrying the third supply voltage (from the terminal structure 122b and through at least the corresponding conductive patterns of the first package substrate 124). In some aspects, the second IC package 140 and the third IC die 180 may be configured and energized by the PMIC 130 in a manner similar to those for the first IC package 120B.

In some aspects, a minimum distance D3 of the conductive paths 112 and 114 between the first IC package 120B and the PMIC 130 may be at least 100 mm to 1000 mm. In some aspects, a minimum distance D4 of a conductive path through one of the terminal structures 122 and the first package substrate 124 may be at least 500 μm to 1000 μm. In some aspects, a conductive path from the PMIC 130 to the first IC die 150 may have a length of at least the summation of the distances D3 and D4, which may cause significant IR drop and parasitic inductance along the conductive path.

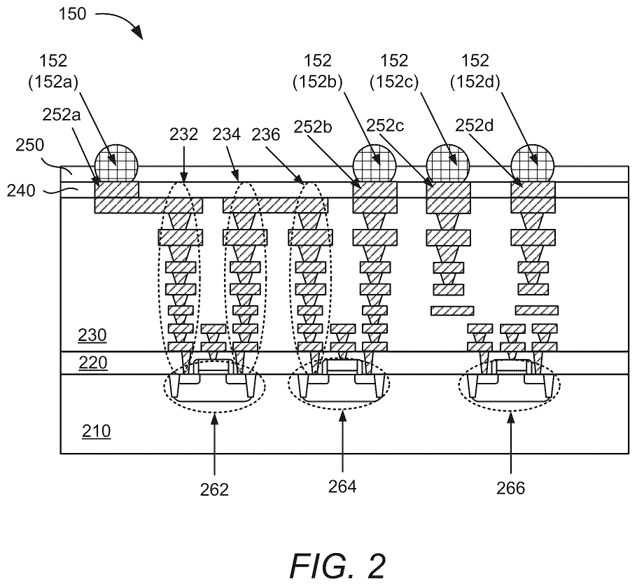

FIG. 2 is a cross-sectional view of a portion of the first IC die 150 in FIG. 1A or FIG. 1B together with the corresponding terminal structures 152, according to aspects of the disclosure. In some aspects, FIG. 2 is a simplified cross-sectional view of a portion of the first IC die 150, and certain details and components of the first IC die 150 may be simplified or omitted in FIG. 2. In some aspects, the components in FIG. 2 that are the same or similar to those in FIGS. 1A and 1B are given the same reference numbers, and detailed description thereof may be omitted. In some aspects, provided that the orientation of first IC die 150 in FIG. 1A or FIG. 1B is defined as a face-up position with respect to the first package substrate 124 (not shown in FIG. 2), the first IC die 150 depicted in FIG. 2 is at a face-down position with respect to the first package substrate 124. Of course, the orientations may be relative to each other and are so described in this disclosure for the purposes of illustration.

In some aspects, the first IC die 150 may include a semiconductor substrate 210, a dielectric layer 220 on the semiconductor substrate 210, and a metallization structure 230 that includes a plurality of metallization layers. In some aspects, each one of the metallization layers may include conductive traces and/or vias surrounded by a dielectric material. In some aspects, the first IC die 150 may further include a top metallization layer 240 on the metallization structure 230, and a passivation layer 250 on the top metallization layer 240. In some aspects, the top metallization layer 240 may include conductive pad structures 252a, 252b, 252c, and 252d. In some aspects, the first IC die 150 may further include terminal structures 152, including the terminal structures 152a, 152b, 152c, and 152d on the conductive pad structures 252a, 252b, 252c, and 252d, respectively.

In some aspects, the first IC die 150 may include active devices, such as metal-oxide-semiconductor field-effect transistors (MOSFETs) 262, 264, and 266. In some aspects, the terminal structure 152a may be configured to carry a supply voltage, such as the second supply voltage described with reference to FIGS. 1A and 1B. In some aspects, the MOSFET 262 may be configured as a power switch to electrically couple or decouple the supply voltage from the terminal structure 152a to or from other electrical components in the first IC die 150. Therefore, in order for the supply voltage to be applied to an active device (e.g., the MOSFET 264) other than the power switch (e.g., the MOSFET 262), the supply voltage may need to electrically coupled through a first stack of conductive traces and vias 232 to reach the MOSFET 262, than coupled through a second stack of conductive traces and vias 234 to reach the upper conductive patterns of the metallization structure 230 (as the PDN may be formed based on the upper conductive patterns that have a lower resistance per square in the first IC die 150), and then coupled through a third stack of conductive traces and vias 236 to reach the MOSFET 264. In some aspects, each one of the stacks of conductive traces and vias 232, 234, and 236 may have a resistance of about 300 ohms.

In some aspects, according to the examples shown in FIGS. 1A, 1B, and 2, the circuit board assembly example 100A or the circuit board assembly example 100B may have an IR drop that takes about 10˜15% of the voltage difference between the second supply voltage and the third supply voltage. In some aspects, the distances D1 and D2, or D3 and D4, of the conductive paths between the first IC die 150 and the PMIC 130 may cause about 60˜80% of the IR drop; and the stacks of conductive traces and vias 232, 234, and 236 may cause about 20˜40% of the IR drop.

In some aspects, implementing the PDN based on backside conductive structures may reduce the portion of the IR dop caused by the stacks of conductive traces and vias 232, 234, and 236, but three conductive stacks of conductive patterns may still be needed in order to reach the power switch and then come back to the PDN. In some aspects, implementing the power switch near the PDN, such as at the upper portion of the metallization structure 230, at the top metallization layer 240, or as a backside active device, may help to reduce the number of stacks of conductive patterns needed before the supply voltage reaches the active device (e.g., the MOSFET 264) from three stacks to one stack in some examples. However, manufacturing active devices at the upper portion of the metallization structure 230, the top metallization layer 240, or the backside of the semiconductor substrate 210 may correspond to increased semiconductor manufacturing complexity, which may lead to increased costs and/or decreased production yields.

In some aspects, capacitive devices may be formed in the metallization structure 230 and electrically coupled to the PDN to reduce the dynamic IR drop (e.g., by providing stored charges for temporary needs of current instead of drawing all the current from the PMIC). However, manufacturing capacitive devices at the metallization structure 230 may still require increased semiconductor manufacturing complexity.

In some aspects, the IC die may include multiple processing cores and may be configured to offer powerful computational capability while also consuming a great amount of power. In some aspects, to accommodate the IR drop, the IC die may lower the operating frequency in order to reduce the power consumption at the cost of reduced circuitry performance. In some aspects, to accommodate the IR drop, the IC die may increase the voltage level of the internal voltage supply (e.g., the second voltage supply illustrated in FIGS. 1A and 1B, increased by 80˜160 mV in some cases) in order to ensure proper signal integrity at a higher operating frequency at the cost of increased power consumption or even increased heat generation.

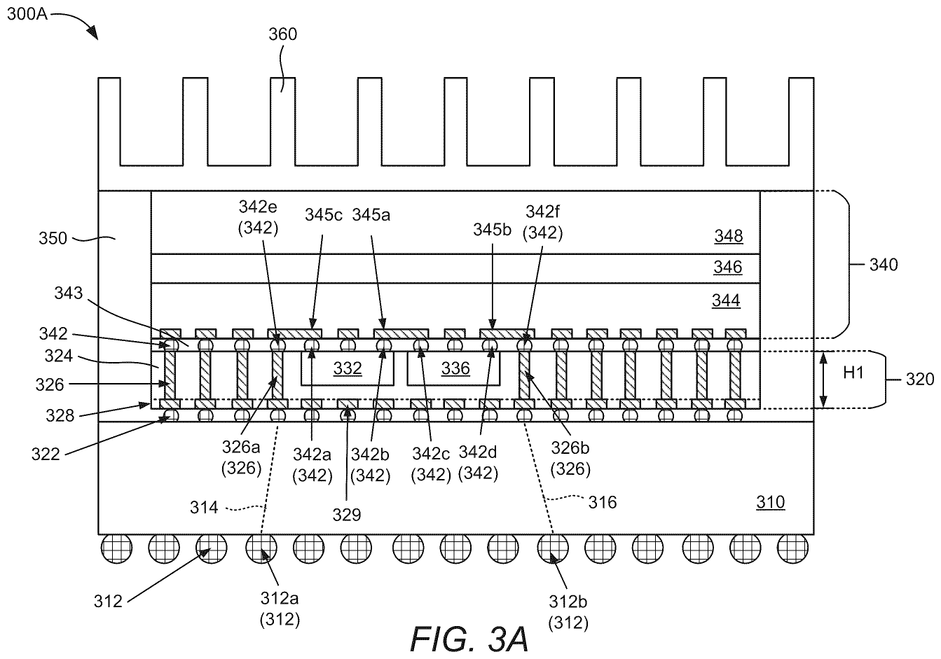

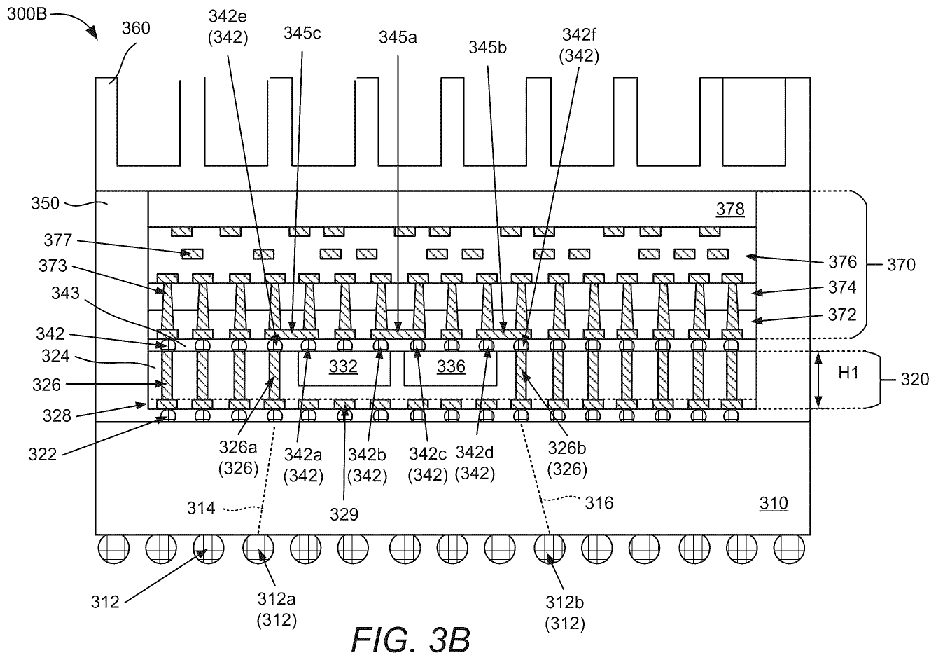

FIG. 3A is a cross-sectional view of a first IC package example 300A, according to aspects of the disclosure. In some aspects, FIG. 3A is a simplified cross-sectional view of a portion of the first IC package example 300A, and certain details and components of the first IC package example 300A may be simplified or omitted in FIG. 3A.

As shown in FIG. 3A, the first IC package example 300A may include a package substrate 310, an interposer 320 on the package substrate 310, and an IC die 340 on the interposer 320. In some aspects, the orientation of the IC die 340 in FIG. 3A may be at a face-up position with respect to the package substrate 310 and/or other components of the first IC package example 300A. Of course, the orientation may be defined in a relative manner and is introduced in this disclosure for the purposes of illustration.

In some aspects, the first IC package example 300A may include a molding portion 350 on the package substrate 310 and surrounding the interposer 320 and the IC die 340. In some aspects, the first IC package example 300A may further include a heat sink 360 on the IC die 340. In some aspects, the package substrate 310 may include terminal structures 312 (e.g., C4 bumps, including terminal structures 312a and 312b) formed on a lower surface of the package substrate 310. In some aspects, the terminal structures 312 may be configured to electrically couple the package substrate 310 to an external component, such as a PCB. In some aspects, the interposer 320 may be mounted on the package substrate 310 through terminal structures 322 (e.g., solder bumps, copper pillar bumps, or copper studs). In some aspects, the IC die 340 may be mounted on the interposer 320 through terminal structures 342 (e.g., solder bumps or copper pillar bumps, including terminal structures 342a˜342f). In some aspects, an underfilling portion 343 may be disposed between the IC die 340 and the interposer 320 and surrounding the terminal structures 342. In some aspects, the molding portion 350 may extend between the interposer 320 and the package substrate 310 and surround the terminal structures 322. In some aspects, a thickness of the interposer 320 may range from 30 μm to 60 μm.

In some aspects, the interposer 320 may include one or more conductive structures 326 (e.g., including conductive structures 326a and 326b) and a dielectric layer 324 surrounding the one or more conductive structures 326. In some aspects, the dielectric layer 324 may include a polymer material. In some aspects, the interposer 320 may include a first interposer metallization structure 328 on one side of the dielectric layer 324 facing the package substrate 310. In some aspects, the first interposer metallization structure 328 may include conductive patterns electrically coupled to the terminal structures 322. In some aspects, at least a portion of the conductive patterns of the first interposer metallization structure 328 may be electrically coupled to the one or more conductive structures 326. In some aspects, the interposer 320 may further include a second interposer metallization structure (not shown) on another side of the dielectric layer 324 facing the IC die 340. In some aspects, the interposer 320 may include a PMIC 332 and a capacitive device 336 embedded in the dielectric layer.

In some aspects, the first interposer metallization structure may include at least one conductive pattern 329 under the PMIC 332. In some aspects, the at least one conductive pattern 329 under the PMIC 332 may be configured for thermal dissipation for the PMIC 332.

In some aspects, based on the IC die 340 at a face-up position with respect to the package substrate 310, the IC die 340 may include a metallization portion 344 facing the interposer 320, a device portion 346 on the metallization portion 344, and a substrate portion 348 on the device portion 346. In some aspects, the metallization portion 344 may include conductive patterns, traces, and vias surrounded by a dielectric material (e.g., including conductive patterns 345a˜345c). In some aspects, the device portion 346 may include various devices and components (e.g., transistors, diodes, resistors, capacitors, and/or inductors).

In some aspects, the package substrate 310 may include a first power node (e.g., corresponding to the terminal structure 312a and the conductive path 314 formed within the package substrate 310) and a second power node (e.g., corresponding to the terminal structure 312b and the conductive path 316 formed within the package substrate 310). In some aspects, the PMIC 332 may include a third power node (e.g., corresponding to a conductive terminal of the PMIC 332 electrically coupled to the terminal structure 342a) and a fourth power node (e.g., corresponding to a conductive terminal of the PMIC 332 electrically coupled to the terminal structure 342b). In some aspects, the IC die 340 may include a fifth power node (e.g., corresponding to the conductive pattern 345a in the metallization portion 344) and a sixth power node (e.g., corresponding to the conductive pattern 345b in the metallization portion 344). In some aspects, the capacitive device 336 may include a seventh power node (e.g., corresponding to a conductive terminal of the capacitive device 336 electrically coupled to the terminal structure 342c) and an eighth power node (e.g., corresponding to a conductive terminal of the capacitive device 336 electrically coupled to the terminal structure 342d).

In some aspects, the third power node may be electrically coupled to the first power node (and further to the conductive path 314 and terminal structure 312a). In some aspects, the third power node may be electrically coupled to the first power node through the conductive structure 326a of the one or more conductive structures 326. In some aspects, the third power node may be electrically coupled to the first power node further through the conductive pattern 345c of the metallization portion 344 of the IC die and terminal structures 342a and 342e.

In some aspects, the fifth power node may be electrically coupled to the fourth power node through, e.g., the conductive pattern 345a and the terminal structure 342b. In some aspects, the sixth power node may be electrically coupled to the second power node through, e.g., the conductive pattern 345b, the terminal structure 342f, and the conductive structure 326b (and further to the conductive path 316 and terminal structure 312b).

In some aspects, the first power node and the third power node may be configured to carry a first supply voltage having a first voltage level. In some aspects, the fourth power node and the fifth power node may be configured to carry a second supply voltage having a second voltage level different from the first voltage level. In some aspects, the second power node and the sixth power node may be configured to carry a third supply voltage having a ground voltage level or a third voltage level different from the first voltage level and the second voltage level.

In some aspects, the IC die 340 may be configured to be energized based on a voltage difference between the fifth power node (carrying the second supply voltage) and the sixth power node (carrying the third supply voltage). In some aspects, the PMIC 332 may include direct current to direct current (DC-DC) conversion capability and may be configured to receive at the third power node (and from the conductive path 314 and terminal structure 312a) the first supply voltage, and output at the fourth power node the second supply voltage. In some aspects, the third supply voltage may be the ground voltage level, the second voltage level may be greater than the ground voltage level and may range from 0.7 V to 1.0 V. In some aspects, the first voltage level may be greater than the second voltage level and may range from 5 V to 12 V.

In some aspects, the PMIC 332 may be further configured to output at the fourth power node the second supply voltage based on the PMIC 332 being at a power-on mode, and to set the fourth power node at an open-circuit state based on the PMIC 332 being at a power-off mode. Accordingly, in some aspects, the IC die 340 may rely upon the PMIC 332 to provide the functionality of the power switch (e.g., the MOSFET 262 in FIG. 2), and the IR drop in other examples caused by the supply voltage coupled through the metallization portion 344 up and down to reach a power switch at a device portion and then back to a PDN at a metallization portion may be reduced or eliminated. Also, by moving the PMIC 332 from outside the IC package (e.g., the examples shown in FIGS. 1A and 1B) to inside the IC package (e.g., the example shown in FIG. 3A), the IR drop in other examples caused by the supply voltage coupled through the conductive path of the PCB may be eliminated. In some aspects, the IR drop for the second supply voltage according to the example shown in FIG. 3A may be about 10˜15% of the IR drop for the second supply voltage according to the examples shown in FIGS. 1A and 1B.

In some aspects, the capacitive device 336 may include a deep trench capacitor structure, a metal-insulator-metal structure, a metal-oxide-metal structure, or a combination thereof. In some aspects, the seventh power node may be electrically coupled to the fourth power node and the fifth power node through, e.g., the terminal structure 342c, the conductive pattern 345a, and the terminal structure 342b. In some aspects, the eighth power node may be electrically coupled to the second power node and the sixth power node through, e.g., the terminal structure 342d, the conductive pattern 345b, the terminal structure 342f, and the conductive structure 326b (and through the conductive path 316 and terminal structure 312b). In some examples, the capacitive device 336 may increase the stability of the voltage difference between the fifth power node and the sixth power node.

FIG. 3B is a cross-sectional view of a second IC package example 300B, according to aspects of the disclosure. In some aspects, FIG. 3B is a simplified cross-sectional view of a portion of the second IC package example 300B, and certain details and components of the second IC package example 300B may be simplified or omitted in FIG. 3B. In some aspects, the second IC package example 300B may be a variation of the first IC package example 300A, and the components in FIG. 3B that are the same or similar to those in FIG. 3A are given the same reference number and detail description thereof may be simplified or omitted.

As shown in FIG. 3B, the second IC package example 300B may include a package substrate 310, an interposer 320 on the package substrate 310, and an IC die 370 on the interposer 320. In some aspects, the orientation of the IC die 370 in FIG. 3B may be at a face-down position with respect to the package substrate 310 and/or other components of the second IC package example 300B. Of course, the orientation may be defined in a relative manner and is introduced in this disclosure for the purposes of illustration.

As shown in FIG. 3B, based on the IC die 370 at a face-down position with respect to the package substrate 310, the IC die 370 may include a substrate portion 372 facing the interposer 320, where the substrate portion 372 may include backside conductive structures 373 and conductive patterns (e.g., including conductive patterns 345a˜345c) formed therein. In some aspects, the IC die 370 may include a device portion 374 on the substrate portion 372, and a metallization portion 376 on the device portion 374. In some aspects, the metallization portion 376 may include conductive patterns, traces, and vias surrounded by a dielectric material (e.g., conductive traces 377). In some aspects, the device portion 374 may include various devices and components (e.g., transistors, diodes, resistors, capacitors, and/or inductors). In some aspects, the backside conductive structures 373 may extend through the device portion 374 and electrically coupled to conductive patterns of the metallization portion 376. As shown in FIG. 3B, the IC die 370 may further include a carrier substrate 378 on the metallization portion 376. In some aspects, the carrier substrate 378 may be omitted.

Similar to the first IC package example 300A, in some aspects, the package substrate 310 of the second IC package example 300B may include a first power node (e.g., corresponding to the terminal structure 312a and the conductive path 314 formed within the package substrate 310) and a second power node (e.g., corresponding to the terminal structure 312b and the conductive path 316 formed within the package substrate 310). In some aspects, the PMIC 332 may include a third power node (e.g., corresponding to a conductive terminal of the PMIC 332 electrically coupled to the terminal structure 342a) and a fourth power node (e.g., corresponding to a conductive terminal of the PMIC 332 electrically coupled to the terminal structure 342b). Also, in some aspects, the IC die 370 may include a fifth power node (e.g., corresponding to the conductive pattern 345a in the substrate portion 372) and a sixth power node (e.g., corresponding to the conductive pattern 345b in the substrate portion 372). In some aspects, the capacitive device 336 may include a seventh power node (e.g., corresponding to a conductive terminal of the capacitive device 336 electrically coupled to the terminal structure 342c) and an eighth power node (e.g., corresponding to a conductive terminal of the capacitive device 336 electrically coupled to the terminal structure 342d).

In some aspects, the electrical connections among the power nodes of the second IC package example 300B may be similar to the electrical connections among the power nodes of the first IC package example 300A, and detailed description thereof is omitted.

In some aspects, the backside conductive structures 373 may be used to form a PDN, and the IC die 370 thus may have a reduced IR drop between the device portion 374 and the PDN. Also, in some aspects, the IC die 370 may rely upon the PMIC 332 to provide the functionality of the power switch (e.g., the MOSFET 262 in FIG. 2), and thus further reduce the IR drop caused by the supply voltage coupled through the backside conductive structures 373 up and down to reach a power switch at a device portion. Also, by moving the PMIC 332 from outside the IC package (e.g., the examples shown in FIGS. 1A and 1B) to inside the IC package (e.g., the example shown in FIG. 3A), the IR drop in other examples caused by the supply voltage coupled through the conductive path of the PCB may be eliminated. In some aspects, the IR drop for the second supply voltage according to the example shown in FIG. 3B may be about 10˜15% of the IR drop for the second supply voltage according to the examples shown in FIGS. 1A and 1B.

In some aspects, the capacitive device 336 may include a deep trench capacitor structure, a metal-insulator-metal structure, a metal-oxide-metal structure, or a combination thereof. In some aspects, the seventh power node may be electrically coupled to the fourth power node and the fifth power node through, e.g., the terminal structure 342c, the conductive pattern 345a, and the terminal structure 342b. In some aspects, the eighth power node may be electrically coupled to the second power node and the sixth power node through, e.g., the terminal structure 342dc, the conductive pattern 345b, the terminal structure 342f, and the conductive structure 326b (and through the conductive path 316 and terminal structure 312b). In some examples, the capacitive device 336 may increase the stability of the voltage difference between the fifth power node and the sixth power node.

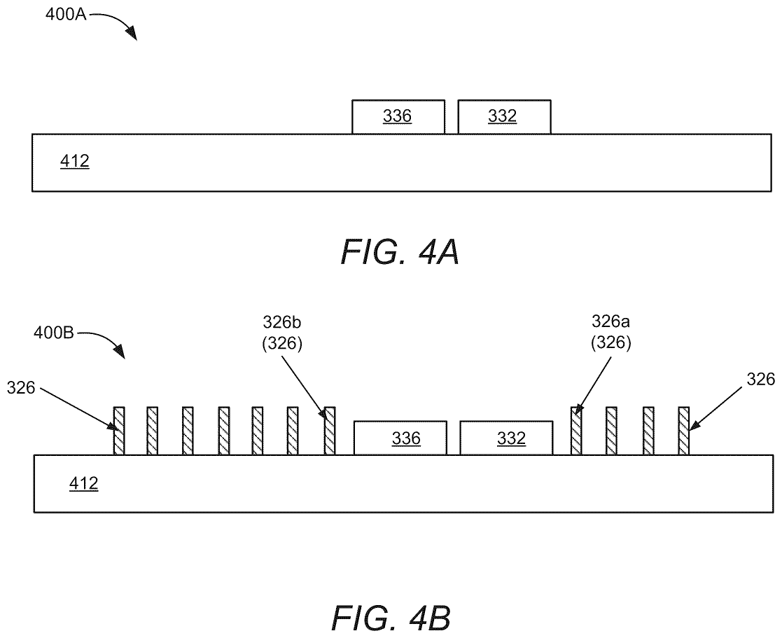

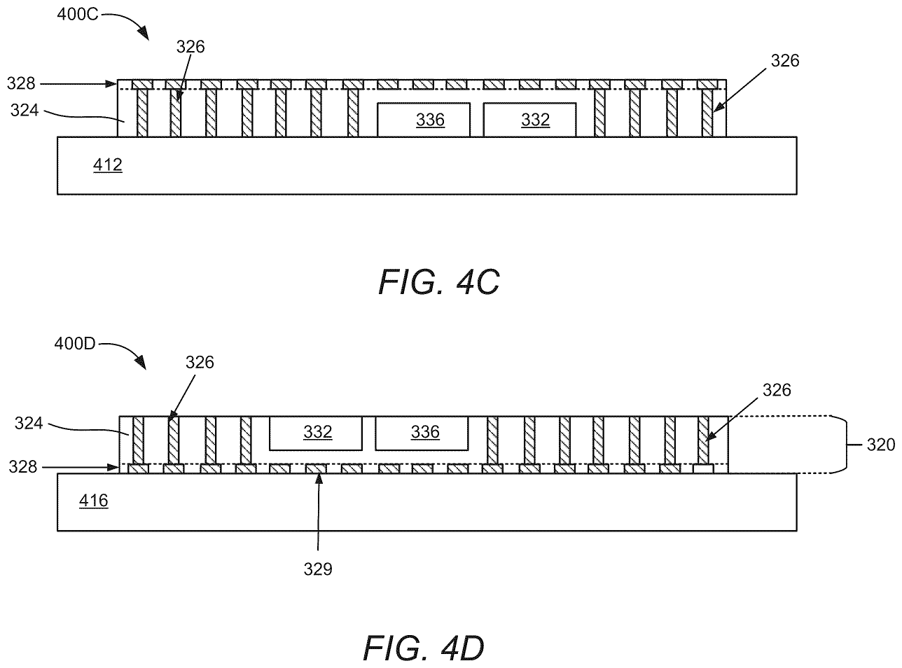

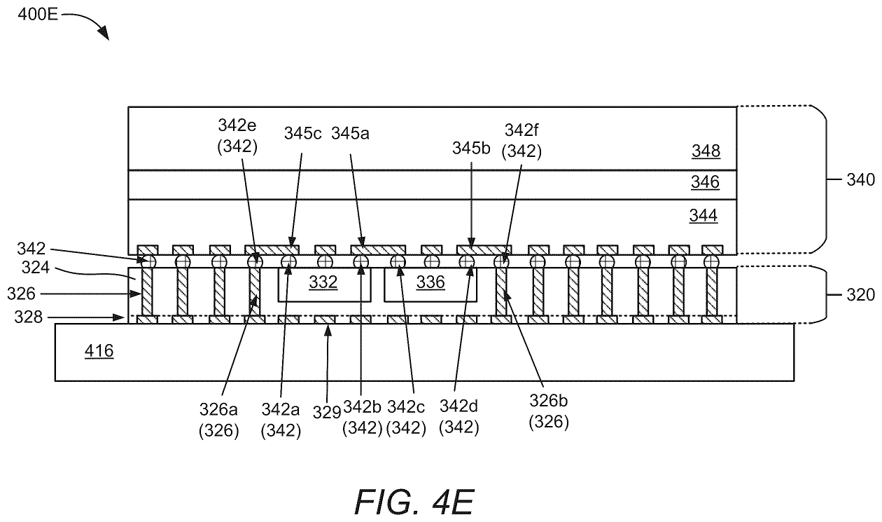

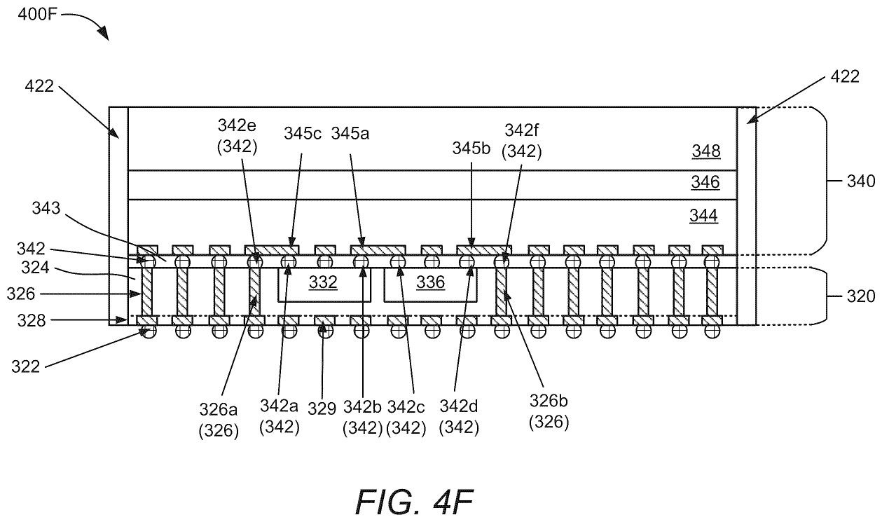

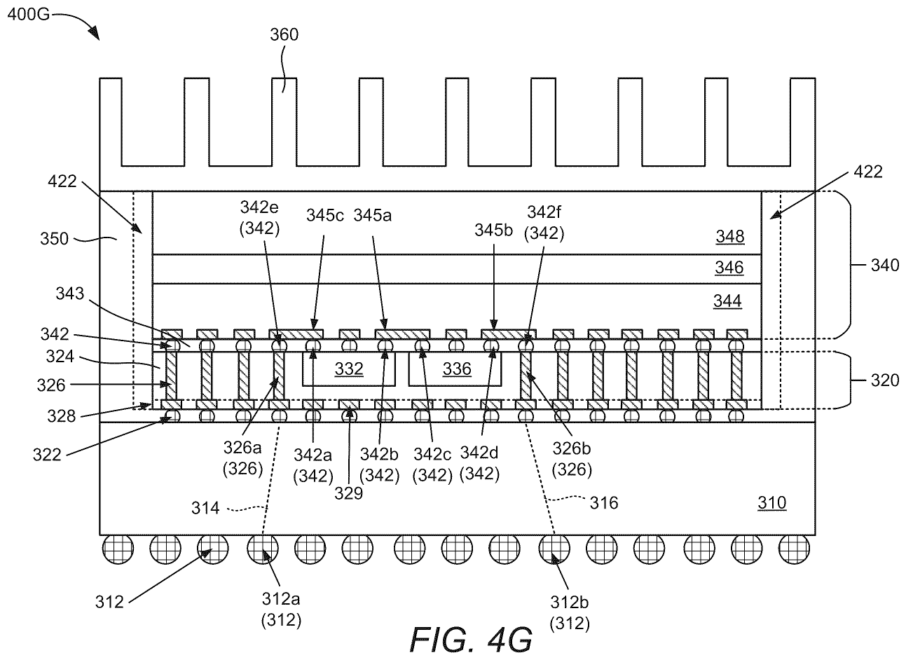

FIGS. 4A-4G illustrate structures at various stages of manufacturing an IC package, such as the first IC package examples 300A in FIG. 3A, based on a first manufacturing process example, according to aspects of the disclosure. The components illustrated in FIGS. 4A-4G that are the same or similar to those of FIG. 3A are given the same reference numbers, and the detailed description thereof may be omitted.

As shown in FIG. 4A, a structure 400A may be formed by disposing an PMIC 332 on a carrier substrate 412. In some aspects, the structure 400A may be formed by further disposing a capacitive device 336 on the carrier substrate 412. In some aspects, the carrier substrate 412 may be a glass substrate or a semiconductor substrate. In some aspects, the PMIC 332 and/or the capacitive device 336 may be mounted on the carrier substrate 412 by a tape or a layer of adhesive material. In some aspects, conductive terminals (not shown) of the PMIC 332 and/or the capacitive device 336 may be on the side of the PMIC 332 and/or the capacitive device 336 that is not facing the carrier substrate 412.

As shown in FIG. 4B, a structure 400B may be formed based on the structure 400A by forming one or more conductive structures 326 (showing a plurality of conductive structures in FIG. 4B, including conductive structures 326a and 326b) on the carrier substrate 412. In some aspects, the one or more conductive structures 326 may include a conductive material (e.g., copper, aluminum, tungsten, or a combination thereof). In some aspects, the one or more conductive structures 326 may be one or more copper pillars or copper studs. In some aspects, the one or more conductive structures 326 may be formed based on first forming a patterned resist layer, disposing the copper based on the patterns defined by the patterned resist layer, and then removing the patterned resist layer. In some aspects, the one or more conductive structures 326 may be formed based on a wire-bonding process. In some aspects, the one or more conductive structures 326 may be formed based on any other suitable process.

As shown in FIG. 4C, a structure 400C may be formed based on the structure 400B by forming a dielectric layer 324 on the carrier substrate 412 and forming a first interposer metallization structure 328, where the dielectric layer 324 may be between the carrier substrate 412 and the first interposer metallization structure 328. In some aspects, the first interposer metallization structure 328 may include conductive patterns, and some of which may be electrically coupled to the respective ones of the one or more conductive structures 326. In some aspects, the dielectric layer 324 may include a polymer material. In some aspects, the first interposer metallization structure 328 may be formed based on various operations including resist layer patterning, copper electroplating, resist layer removal, and/or dielectric build-up firm lamination.

As shown in FIG. 4D, a structure 400D may be formed based on the structure 400C by detaching the carrier substrate 412 from an assembly that include the dielectric layer 324, the PMIC 332, the one or more conductive structures 326, the first interposer metallization structure 328, and/or the capacitive device 336. The structure 400D may be formed further based on flipping the aforementioned assembly and disposing the aforementioned assembly on a second carrier substrate 416. In some aspects, as shown in FIG. 4D, the dielectric layer 324, one or more conductive structures 326, the first interposer metallization structure 328, the PMIC 332, and the capacitive device 336 may constitute an interposer 320.

As shown in FIG. 4D, the first interposer metallization structure 328 is formed on one side of the dielectric layer 324 facing the second carrier substrate 416. In some aspects, at least one conductive pattern 329 of the first interposer metallization structure 328 may be under the PMIC 332 and may be configured for thermal dissipation for the PMIC 332. In some aspects, the interposer 320 may be formed further based on forming a second interposer metallization structure (not shown) on another side of the dielectric layer 324 not facing the second carrier substrate 416, and may have conductive patterns in contact with the conductive terminals of the PMIC 332 and/or the capacitive device 336.

As shown in FIG. 4E, a structure 400E may be formed based on the structure 400D by disposing an IC die 340 on the interposer 320. In some aspects, a plurality of terminal structures 342 (e.g., solder bumps or copper pillar bumps, including terminal structures 342a˜342f) may be formed on a lower side of the IC die 340, and the IC die 340 may be mounted on the interposer 320 through the terminal structures 342. In some aspects, the orientation of the IC die 340 in FIG. 4E may be at a face-up position on the interposer 320.

In some aspects, the IC die 340 may include a metallization portion 344 facing the interposer 320, a device portion 346 on the metallization portion 344, and a substrate portion 348 on the device portion 346. In some aspects, the metallization portion 344 may include conductive patterns, traces, and vias surrounded by a dielectric material (e.g., including conductive patterns 345a˜345c). The details regarding various elements of the IC die 340 and the interposer 320 and the electrical connections thereof may be similar to those discussed with reference to FIG. 3A.

As shown in FIG. 4F, a structure 400F may be formed based on the structure 400E by disposing an underfilling portion 343 between the IC die 340 and the interposer 320 and surrounding the terminal structures 342, and detaching the second carrier substrate 416 from the interposer 320. In some aspects, the structure 400F may be formed further based on forming a molding portion 422 on the sidewalls of the IC die 340, the interposer 320, and the underfilling portion 343. In some aspects, the underfilling portion 343 and the molding portion 422 may be formed based on a same molding process. In some aspects, the structure 400F may be formed further based on forming terminal structures 322 (e.g., solder bumps, copper pillar bumps, or copper studs) on a lower side of the interposer 320.

As shown in FIG. 4G, a structure 400G that corresponds to the IC package 300A may be formed. In some aspects, the structure 400G may be formed based on mounting the structure 400F on a package substrate 310 through the terminal structures 322, and forming a molding portion 350 (incorporating the molding portion 422) on the package substrate 310 and surrounding the interposer 320 and the IC die 340. In some aspects, the molding portion 350 may extend between the interposer 320 and the package substrate 310 and surround the terminal structures 322. In some aspects, the structure 400G may be formed further based on forming a heat sink 360 on the IC die 340. In some aspects, the structure 400G may include terminal structures 312 (e.g., C4 bumps, including terminal structures 312a and 312b) formed on a lower side of the package substrate 310, either before or after the structure 400F being mounted on the package substrate 310.

While the IC die 340 is illustrated in FIGS. 4E-4G as a non-limiting example for forming the IC package 300A as illustrated in FIG. 3A, the IC die 370 as shown in FIG. 3B may be mounted on the interposer 320 in place of the IC die 340 in FIGS. 4E-4G for forming the IC package 300B as illustrated in FIG. 3B.

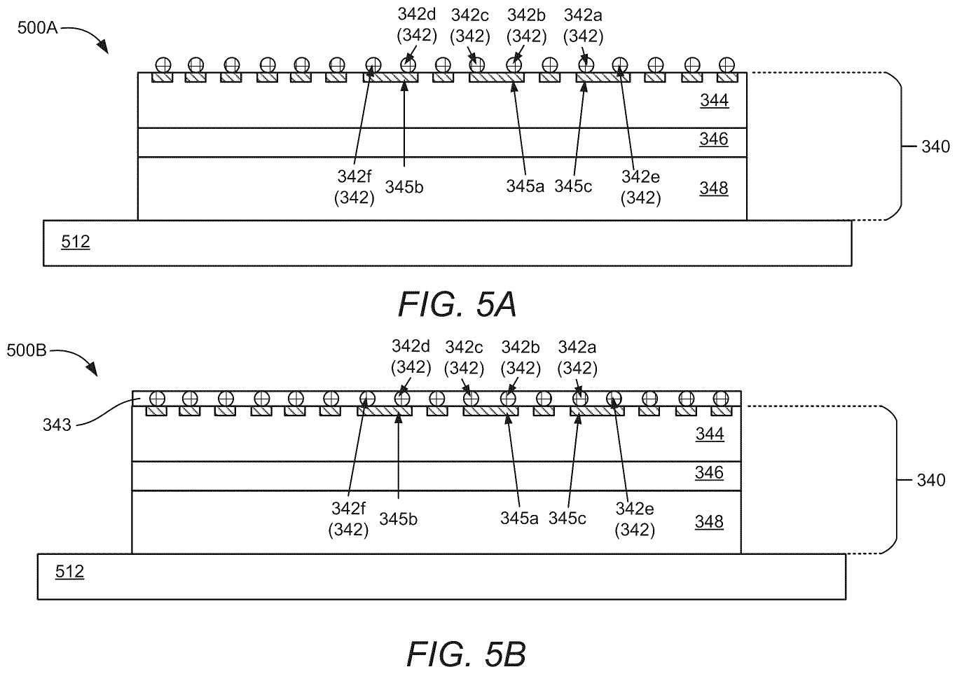

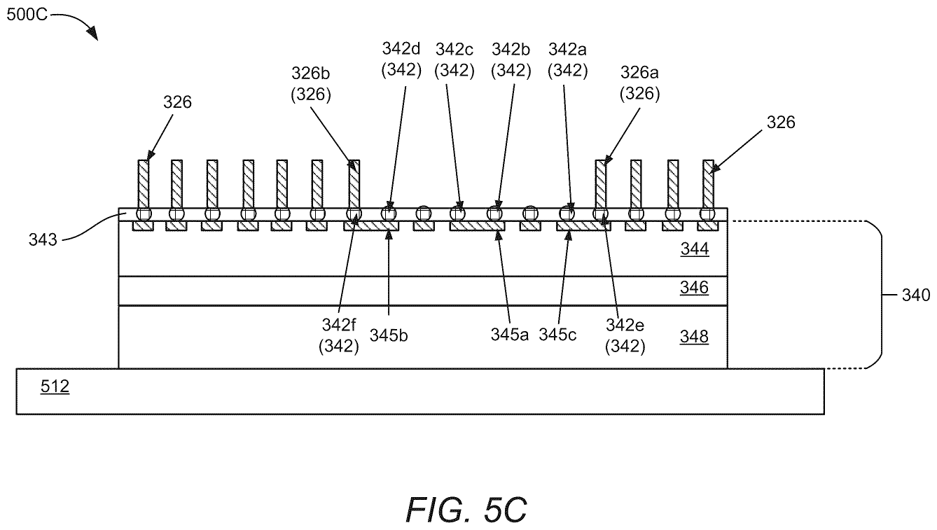

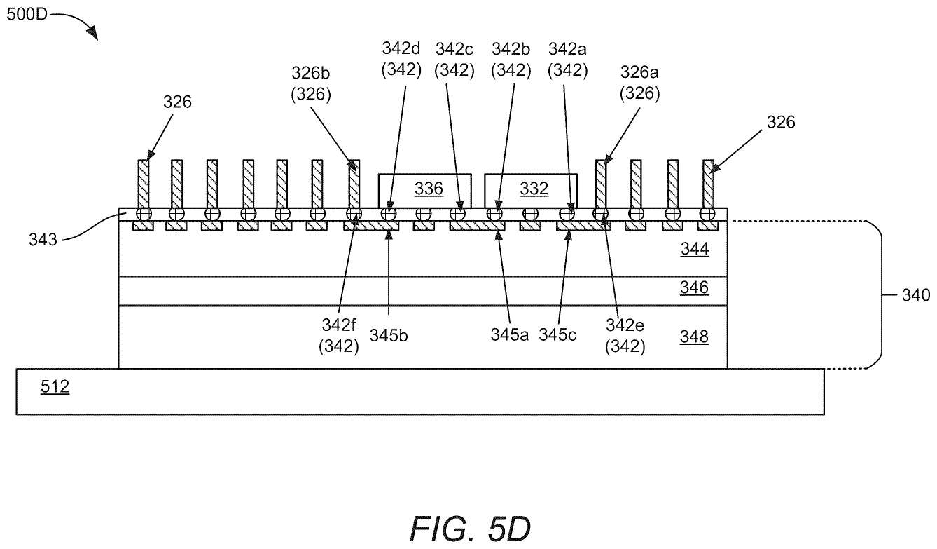

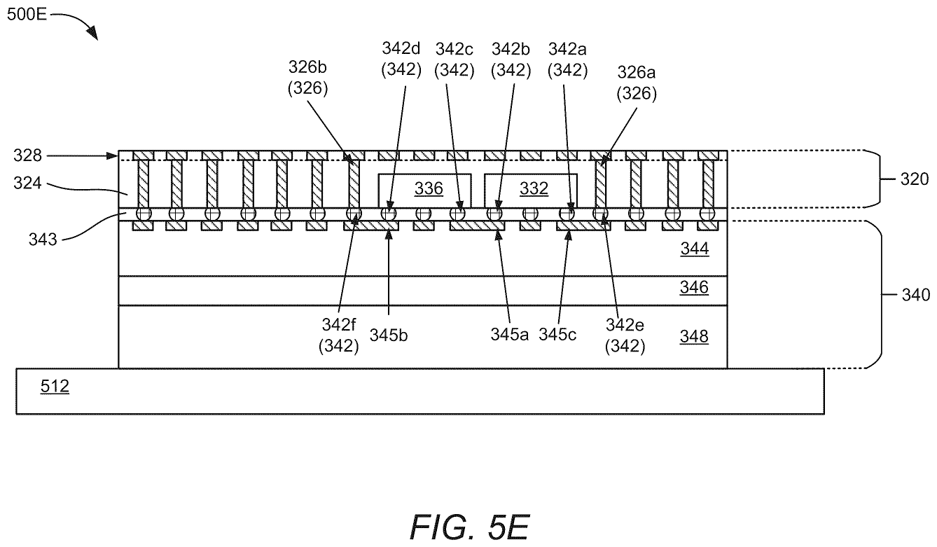

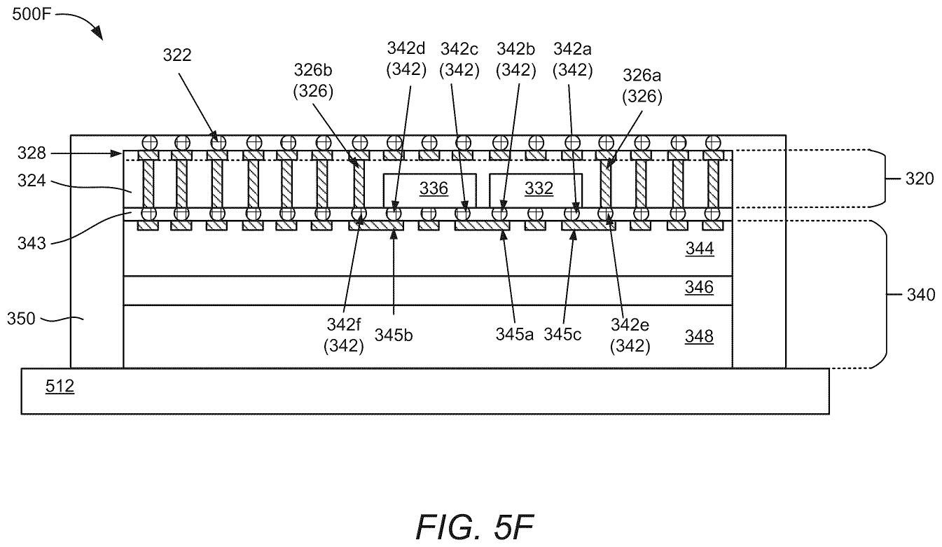

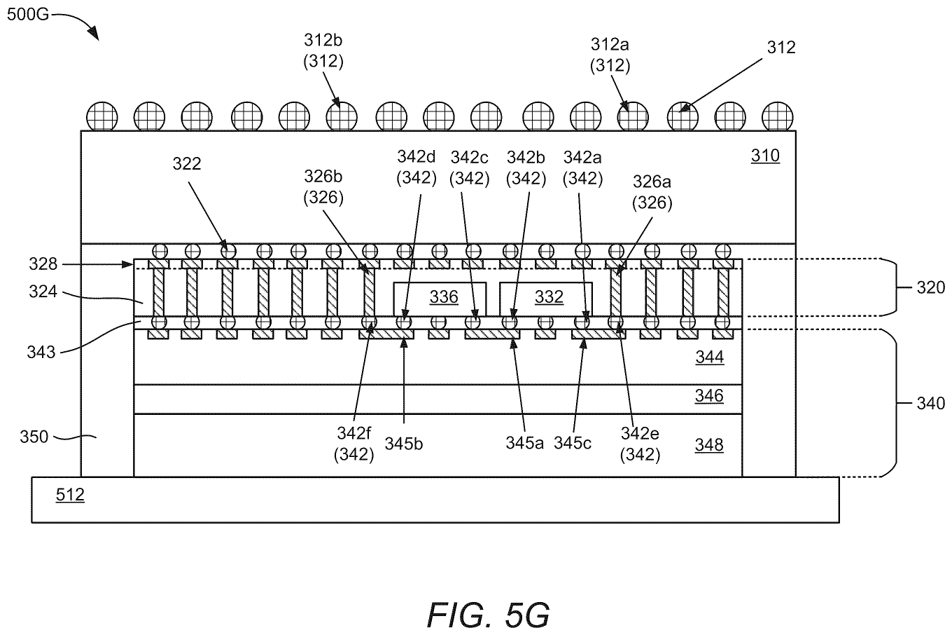

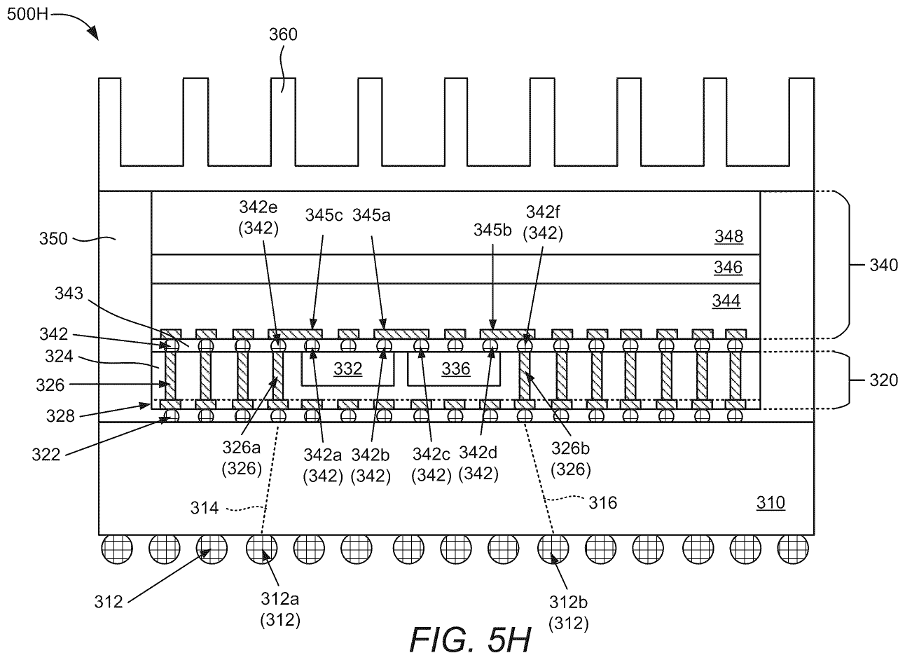

FIGS. 5A-5H illustrate structures at various stages of manufacturing an IC package, such as the first IC package examples 300A in FIG. 3A, based on a second manufacturing process example, according to aspects of the disclosure. The components illustrated in FIGS. 5A-5H that are the same or similar to those of FIG. 3A are given the same reference numbers, and the detailed description thereof may be omitted.

As shown in FIG. 5A, a structure 500A may be formed by disposing an IC die 340 on a carrier substrate 512. In some aspects, the carrier substrate 512 may be a glass substrate or a semiconductor substrate. In some aspects, the IC die 340 may include a metallization portion 344, a device portion 346, and a substrate portion 348. In some aspects, the metallization portion 344 may include conductive patterns, traces, and vias surrounded by a dielectric material (e.g., including conductive patterns 345a˜345c). The details regarding various elements of the IC die 340 may be similar to those discussed with reference to FIG. 3A. In some aspects, the orientation of the IC die 340 in FIG. 5A may be at a face-down position on the carrier substrate 512.

In some aspects, the structure 500A may further include a plurality of terminal structures 342 (e.g., solder bumps or copper pillar bumps, including terminal structures 342a˜342f) on the IC die 340. In some aspects, the terminal structures 342 may be formed on the IC die 340 before or after the IC die 340 being mounted on the carrier substrate 512.

As shown in FIG. 5B, a structure 500B may be formed based on the structure 500A by disposing an underfilling portion 343 on a lower side of the IC die 340 (the IC die 340 being at a face-down position in FIG. 5B) and surrounding the terminal structures 342. In some aspects, the underfilling portion 343 may be formed by forming a layer of molding materials on the lower side of the IC die 340 and griding the layer of molding materials to expose the terminal structures 342.

As shown in FIG. 5C, a structure 500C may be formed based on the structure 500B by forming one or more conductive structures 326 (showing a plurality of conductive structures in FIG. 5C, including conductive structures 326a and 326b) on the underfilling portion 343 and the terminal structures 342 and electrically coupled to the terminal structures 342. In some aspects, the one or more conductive structures 326 may include a conductive material (e.g., copper, aluminum, tungsten, or a combination thereof). In some aspects, the one or more conductive structures 326 may be one or more copper pillars or copper studs. In some aspects, the one or more conductive structures 326 may be formed based on first forming a patterned resist layer, disposing the copper based on the patterns defined by the patterned resist layer, and then removing the patterned resist layer. In some aspects, the one or more conductive structures 326 may be formed based on a wire-bonding process. In some aspects, the one or more conductive structures 326 may be formed based on any other suitable process.

In some aspects, prior to forming the one or more conductive structures 326, an interposer metallization layer (not shown) may be formed on the underfilling portion 343 and the terminal structures 342, and then the one or more conductive structures 326 may be disposed on the interposer metallization layer.

As shown in FIG. 5D, a structure 500D may be formed based on the structure 500C by disposing a PMIC 332 on the underfilling portion 343 and the terminal structures 342 (or on the interposer metallization layer, if applicable). In some aspects, the structure 500D may be formed by further disposing a capacitive device 336 on the underfilling portion 343 and the terminal structures 342 (or on the interposer metallization layer, if applicable). In some aspects, the PMIC 332 and/or the capacitive device 336 may include conductive terminals (not shown) facing the IC die 340, and the PMIC 332 and/or the capacitive device 336 may be mounted on the IC die 340 through connecting the conductive terminals of the PMIC 332 and/or the capacitive device 336 to the terminal structures 342 directly without the interposer metallization layer, or indirectly through the interposer metallization layer when the interposer metallization layer is formed.

As shown in FIG. 5E, a structure 500E may be formed based on the structure 500D by forming a dielectric layer 324 on the underfilling portion 343 (or on the interposer metallization layer on which the PMIC 332 and/or the capacitive device 336 are disposed, if available) and forming another interposer metallization structure 328 on the dielectric layer 324. In some aspects, the interposer metallization structure 328 may include conductive patterns, and some of which may be electrically coupled to the respective ones of the one or more conductive structures 326. In some aspects, the dielectric layer 324 may include a polymer material. In some aspects, the interposer metallization structure 328 may be formed based on various operations including resist layer patterning, copper electroplating, resist layer removal, and/or dielectric build-up firm lamination.

In some aspects, as shown in FIG. 5E, the dielectric layer 324, one or more conductive structures 326, the interposer metallization structure 328, the PMIC 332, and the capacitive device 336 may constitute an interposer 320.

As shown in FIG. 5F, a structure 500F may be formed based on the structure 500E by forming terminal structures 322 (e.g., solder bumps, copper pillar bumps, or copper studs) on a lower side of the interposer 320 and electrically coupled to the interposer metallization structure 328 of the interposer 320. In some aspects, the structure 500F may be formed further based on forming a molding portion 350 on the carrier substrate 512 and surrounding the interposer 320 and the IC die 340. In some aspects, the molding portion 350 may surround the terminal structures 322.

As shown in FIG. 5G, a structure 500G may be formed based on the structure 500F by disposing a package substrate 310 on the structure 500F. In some aspects, the structure 500G may include terminal structures 312 (e.g., C4 bumps, including terminal structures 312a and 312b) formed on a lower side of the package substrate 310, either before or after the package substrate 310 being mounted on the structure 500F.

As shown in FIG. 5H, a structure 500H that corresponds to the IC package 300A may be formed. In some aspects, the structure 500H may be formed based on detaching the carrier substrate 512 from the molding portion 350 and the IC die 340. In some aspects, the structure 500H may be formed further based on forming a heat sink 360 on the IC die 340 (on the side opposing to the interposer 320 and the package substrate 310).

While the IC die 340 is illustrated in FIGS. 5A-5H as a non-limiting example for forming the IC package 300A as illustrated in FIG. 3A, the IC die 370 as shown in FIG. 3B may be mounted on the interposer 320 in place of the IC die 340 in FIGS. 5A-5H for forming the IC package 300B as illustrated in FIG. 3B.

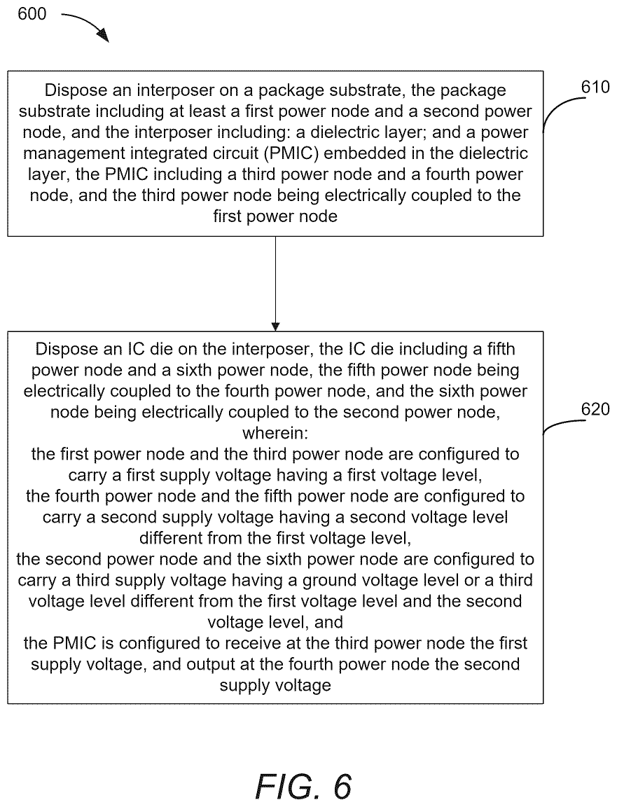

FIG. 6 illustrates a method 600 for manufacturing an IC package (such as the first IC package example 300A in FIG. 3A, the second IC package example 300B in FIG. 3B, the structure 400G in FIG. 4G, and/or the structure 500H in FIG. 5H), according to aspects of the disclosure. In some aspects, FIGS. 4A-4G and FIGS. 5A-5H may depict the structures at various stages of manufacturing an IC package according to the method 600.

At operation 610, an interposer (e.g., the interposer 320) can be disposed on a package substrate (e.g., the package substrate 310). In some aspects, the package substrate may include at least a first power node (e.g., corresponding to the terminal structure 312a) and a second power node (e.g., corresponding to the terminal structure 312b). In some aspects, the interposer may include a dielectric layer (e.g., the dielectric layer 324) and a PMIC (e.g., the PMIC 332) embedded in the dielectric layer. In some aspects, the PMIC may include a third power node (e.g., corresponding to a contact terminal coupled to the terminal structures 342a) and a fourth power node (e.g., corresponding to a contact terminal coupled to the terminal structures 342b). In some aspects, the third power node may be electrically coupled to the first power node. In some aspects, a thickness of the interposer may range from 30 μm to 60 μm.

At operation 620, an IC die (e.g., the IC die 340 or the IC die 370) can be disposed on the interposer. In some aspects, the IC die may include a fifth power node (e.g., corresponding to the conductive patterns 345a) and a sixth power node (e.g., corresponding to the conductive patterns 345b). In some aspects, the IC die may be configured to be energized at least based on a voltage difference between the fifth power node and the sixth power node. In some aspects, the fifth power node may be electrically coupled to the fourth power node. In some aspects, the sixth power node may be electrically coupled to the second power node.

In some aspects, the first power node and the third power node may be configured to carry a first supply voltage having a first voltage level. In some aspects, the fourth power node and the fifth power node may be configured to carry a second supply voltage having a second voltage level different from the first voltage level. In some aspects, the second power node and the sixth power node may be configured to carry a third supply voltage having a ground voltage level or a third voltage level different from the first voltage level and the second voltage level.

In some aspects, the third supply voltage may be the ground voltage level, the second voltage level may be greater than the ground voltage level and may range from 0.7 V to 1.0 V. In some aspects, the first voltage level may be greater than the second voltage level and may range from 5 V to 12 V. In some aspects, the PMIC may be configured to receive at the third power node the first supply voltage, and output at the fourth power node the second supply voltage.

In some aspects, as illustrated in FIGS. 4A-4C, the method 600 may further include forming the interposer, including disposing the PMIC on a carrier substrate (e.g., the carrier substrate 412), forming one or more conductive structures (e.g., the one or more conductive structures 326) on the carrier substrate, and forming the dielectric layer on the carrier substrate. In some aspects, the dielectric layer may cover the PMIC and may surround the one or more conductive structures. In some aspects, the forming of the interposer may further include detaching the carrier substrate from the dielectric layer, the PMIC, and the one or more conductive structures.

In some aspects, as illustrated in FIGS. 5C-5E, the disposing the IC die on the interposer may be based on forming one or more conductive structures (e.g., the one or more conductive structures 326) on one side of the IC die, disposing the PMIC on the side of the IC die, forming the dielectric layer on the IC die, and forming an interposer metallization structure (e.g., the interposer metallization structure 328) on the on the dielectric layer such that the dielectric layer is between the interposer metallization structure and the IC die. In some aspects, the dielectric layer may cover the PMIC and surround the one or more conductive structures.

In some aspects, either based on FIGS. 4A-4G or FIGS. 5A-5H, the forming the interposer may include forming the one or more conductive structures (e.g., the one or more conductive structures 326) in the interposer, where the dielectric layer may surround the one or more conductive structures. In some aspects, the third power node may be electrically coupled to the first power node through a first conductive structure (e.g., conductive structure 326a) of the one or more conductive structures.

In some aspects, the forming the interposer may further include disposing a capacitive device (e.g., the capacitive device 336) embedded in the dielectric layer. In some aspects, the capacitive device including a seventh power node (e.g., corresponding to a contact terminal coupled to the terminal structures 342c) and an eighth power node (e.g., corresponding to a contact terminal coupled to the terminal structures 342d). in some aspects, the seventh power node may be electrically coupled to the fourth power node and the fifth power node. In some aspects, the eighth power node may be electrically coupled to the second power node and the sixth power node.

In some aspects, the forming the interposer may include forming a first interposer metallization structure on one side of the dielectric layer on one side of, forming a second interposer metallization structure on another side of the dielectric layer another side of, or a combination thereof.

A technical advantage of the method 600 may correspond to manufacturing an IC package that includes an interposer with an embedded PMIC. In some aspects, by relying upon the PMIC to provide the functionality of the power switch for the IC die in the IC package, the IR drop caused by the supply voltage coupled through a metallization portion of the IC die up and down to reach a power switch of the IC die and then back to a PDN of the IC die may be reduced or eliminated. Also, by having the PMIC inside the IC package, the IR drop caused by the supply voltage coupled through the conductive path of a PCB may be eliminated. In some aspects, the capacitive device may increase the stability of the supply voltages.

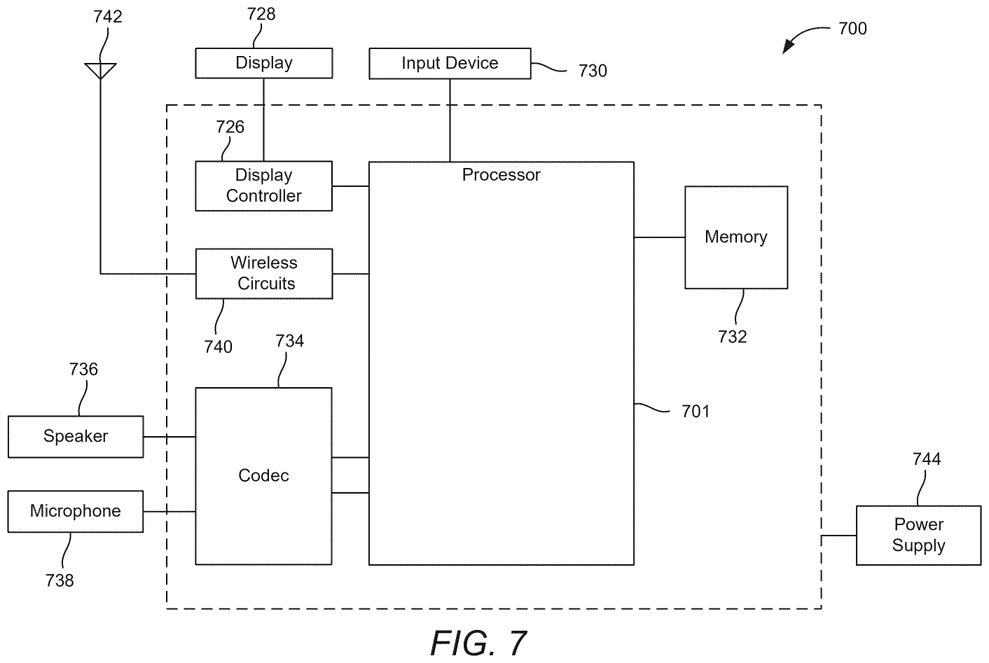

FIG. 7 illustrates a mobile device 700, according to aspects of the disclosure. In some aspects, the mobile device 700 may be implemented by including one or more IC devices that include interposers with an embedded PMIC as disclosed herein.

In some aspects, mobile device 700 may be configured as a wireless communication device. As shown, mobile device 700 includes processor 701. Processor 701 may be communicatively coupled to memory 732 over a link, which may be a die-to-die or chip-to-chip link. Mobile device 700 also includes display 728 and display controller 726, with display controller 726 coupled to processor 701 and to display 728. The mobile device 700 may include input device 730 (e.g., physical, or virtual keyboard), power supply 744 (e.g., battery), speaker 736, microphone 738, and wireless antenna 742. In some aspects, the power supply 744 may directly or indirectly provide the supply voltage for operating some or all of the components of the mobile device 700.

In some aspects, FIG. 7 may include coder/decoder (CODEC) 734 (e.g., an audio and/or voice CODEC) coupled to processor 701; speaker 736 and microphone 738 coupled to CODEC 734; and wireless circuits 740 (which may include a modem, RF circuitry, filters, etc.) coupled to wireless antenna 742 and to processor 701.

In some aspects, one or more of processor 701 (e.g., SoCs, application processor (AP)), display controller 726, memory 732, CODEC 734, and wireless circuits 740 (e.g., baseband interface) including IC devices that are packaged as IC packages and including interposers with an embedded PMIC according to the various aspects described in this disclosure.

It should be noted that although FIG. 7 depicts a mobile device 700, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

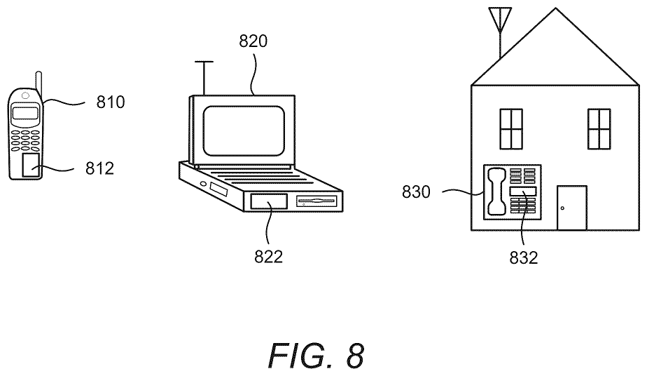

FIG. 8 illustrates various electronic devices 810, 820, and 830 that may incorporate IC devices 812, 822, and 832, which may be put into the IC packages as described herein, according to aspects of the disclosure.

For example, a mobile phone device 810, a laptop computer device 820, and a fixed location terminal device 830 may each be considered generally user equipment (UE) and may include one or more IC devices, such as IC devices 812, 822, and 832, and a power supply to provide the supply voltages to power the IC devices. The IC devices 812, 822, and 832 may be, for example, correspond to an IC device packaged as an IC package having an interposer manufactured based on the examples described above with reference to FIGS. 2 and 3A-3E.

The devices 810, 820, and 830 illustrated in FIG. 8 are merely non-limiting examples. Other electronic devices may also feature the IC devices including interposers as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-8 may be rearranged and/or combined into a single component, process, feature, or function or incorporated in several components, processes, or functions. Additional elements, components, processes, and/or functions may also be added without departing from the disclosure. In some implementations, FIGS. 1-8 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

### IMPLEMENTATION EXAMPLES ARE DESCRIBED IN THE FOLLOWING NUMBERED CLAUSES

Clause 1. An integrated circuit (IC) package, comprising: a package substrate including at least a first power node and a second power node; an interposer on the package substrate, the interposer including: a dielectric layer; and a power management integrated circuit (PMIC) embedded in the dielectric layer, the PMIC including a third power node and a fourth power node, and the third power node being electrically coupled to the first power node; and an IC die on the interposer, the IC die including a fifth power node and a sixth power node, the fifth power node being electrically coupled to the fourth power node, and the sixth power node being electrically coupled to the second power node, wherein: the first power node and the third power node are configured to carry a first supply voltage having a first voltage level, the fourth power node and the fifth power node are configured to carry a second supply voltage having a second voltage level different from the first voltage level, the second power node and the sixth power node are configured to carry a third supply voltage having a ground voltage level or a third voltage level different from the first voltage level and the second voltage level, and the PMIC is configured to receive at the third power node the first supply voltage, and output at the fourth power node the second supply voltage.

Clause 2. The IC package of clause 1, wherein: the PMIC is further configured to output at the fourth power node the second supply voltage based on the PMIC being at a power-on mode and to set the fourth power node at an open-circuit state based on the PMIC being at a power-off mode.

Clause 3. The IC package of any of clauses 1 to 2, wherein: the interposer further comprises one or more conductive structures, the dielectric layer surrounding the one or more conductive structures, and the third power node is electrically coupled to the first power node through a first conductive structure of the one or more conductive structures.

Clause 4. The IC package of clause 3, wherein: each of the one or more conductive structures comprises a copper stud.

Clause 5. The IC package of any of clauses 1 to 4, wherein the interposer further comprises: a first interposer metallization structure on one side of the dielectric layer facing the package substrate, a second interposer metallization structure on another side of the dielectric layer facing the IC die, or a combination thereof.

Clause 6. The IC package of clause 5, wherein: the first interposer metallization structure comprises at least one conductive pattern under the PMIC.

Clause 7. The IC package of clause 6, wherein the at least one conductive pattern under the PMIC is configured for thermal dissipation for the PMIC.

Clause 8. The IC package of any of clauses 1 to 7, wherein the dielectric layer comprises a polymer material.

Clause 9. The IC package of any of clauses 1 to 8, wherein: the interposer further comprises a capacitive device including a seventh power node and an eighth power node, the seventh power node is electrically coupled to the fourth power node and the fifth power node, and the eighth power node is electrically coupled to the second power node and the sixth power node.

Clause 10. The IC package of clause 9, wherein the capacitive device comprises: a deep trench capacitor structure, a metal-insulator-metal structure, a metal-oxide-metal structure, or a combination thereof.

Clause 11. The IC package of any of clauses 1 to 10, wherein the IC die comprises: based on the IC die at a face-up position with respect to the package substrate, a metallization portion facing the interposer, a device portion on the metallization portion, and a substrate portion on the device portion; or based on the IC die at a face-down position with respect to the package substrate, the substrate portion facing the interposer and including backside conductive structures formed therein, a device portion on the substrate portion, and a metallization portion on the device portion.

Clause 12. The IC package of clause 11, wherein: the third power node is electrically coupled to the first power node through a conductive pattern of the metallization portion of the IC die, a portion of the backside conductive structures, or a combination thereof.

Clause 13. The IC package of any of clauses 1 to 12, wherein a thickness of the interposer ranges from 30 micrometers (μm) to 60 μm.

Clause 14. A method of manufacturing an integrated circuit (IC) package, comprising: disposing an interposer on a package substrate, the package substrate including at least a first power node and a second power node, and the interposer including: a dielectric layer; and a power management integrated circuit (PMIC) embedded in the dielectric layer, the PMIC including a third power node and a fourth power node, and the third power node being electrically coupled to the first power node; and disposing an IC die on the interposer, the IC die including a fifth power node and a sixth power node, the fifth power node being electrically coupled to the fourth power node, and the sixth power node being electrically coupled to the second power node, wherein: the first power node and the third power node are configured to carry a first supply voltage having a first voltage level, the fourth power node and the fifth power node are configured to carry a second supply voltage having a second voltage level different from the first voltage level, the second power node and the sixth power node are configured to carry a third supply voltage having a ground voltage level or a third voltage level different from the first voltage level and the second voltage level, and the PMIC is configured to receive at the third power node the first supply voltage, and output at the fourth power node the second supply voltage.

Clause 15. The method of clause 14, further comprising forming the interposer, comprising: disposing the PMIC on a carrier substrate; forming one or more conductive structures on the carrier substrate; forming the dielectric layer on the carrier substrate, the dielectric layer covering the PMIC and surrounding the one or more conductive structures; and detaching the carrier substrate from the dielectric layer, the PMIC, and the one or more conductive structures.

Clause 16. The method of clause 14, wherein the disposing the IC die on the interposer is based on forming the interposer on a side of the IC die, comprising: forming one or more conductive structures on the side of IC die; disposing the PMIC on the side of the IC die; forming the dielectric layer on the side of the IC die, the dielectric layer covering the PMIC and surrounding the one or more conductive structures; and forming an interposer metallization structure on the dielectric layer such that the dielectric layer is between the interposer metallization structure and the IC die.

Clause 17. The method of any of clauses 14 to 16, further comprising forming the interposer, comprising: forming one or more conductive structures in the interposer, the dielectric layer surrounding the one or more conductive structures, wherein the third power node is electrically coupled to the first power node through a first conductive structure of the one or more conductive structures.

Clause 18. The method of any of clauses 14 to 17, further comprising forming the interposer, comprising: forming a first interposer metallization structure on one side of the dielectric layer facing the package substrate, forming a second interposer metallization structure on another side of the dielectric layer facing the IC die, or a combination thereof.

Clause 19. The method of clause 18, wherein: the first interposer metallization structure comprises at least one conductive pattern under the PMIC.

Clause 20. The method of any of clauses 14 to 19, further comprising forming the interposer, comprising: disposing a capacitive device embedded in the dielectric layer, the capacitive device including a seventh power node and an eighth power node, wherein: the seventh power node is electrically coupled to the fourth power node and the fifth power node, and the eighth power node is electrically coupled to the second power node and the sixth power node.

Clause 21. The method of any of clauses 14 to 20, wherein a thickness of the interposer ranges from 30 micrometers (μm) to 60 μm.

Clause 22. An electronic device, comprising: an integrated circuit (IC) package that comprises: a package substrate including at least a first power node and a second power node; an interposer on the package substrate, the interposer including: a dielectric layer; and a power management integrated circuit (PMIC) embedded in the dielectric layer, the PMIC including a third power node and a fourth power node, and the third power node being electrically coupled to the first power node; and an IC die on the interposer, the IC die including, a fifth power node and a sixth power node, the fifth power node being electrically coupled to the fourth power node, and the sixth power node being electrically coupled to the second power node, wherein: the first power node and the third power node are configured to carry a first supply voltage having a first voltage level, the fourth power node and the fifth power node are configured to carry a second supply voltage having a second voltage level different from the first voltage level, the second power node and the sixth power node are configured to carry a third supply voltage having a ground voltage level or a third voltage level different from the first voltage level and the second voltage level, and the PMIC is configured to receive at the third power node the first supply voltage, and output at the fourth power node the second supply voltage.

Clause 23. The electronic device of clause 22, wherein: the PMIC is further configured to output at the fourth power node the second supply voltage based on the PMIC being at a power-on mode and to set the fourth power node at an open-circuit state during based on the PMIC being at a power-off mode.

Clause 24. The electronic device of any of clauses 22 to 23, wherein: the interposer further comprises one or more conductive structures, the dielectric layer surrounding the one or more conductive structures, and the third power node is electrically coupled to the first power node through a first conductive structure of the one or more conductive structures.

Clause 25. The electronic device of any of clauses 22 to 24, wherein the interposer further comprises: a first interposer metallization structure on one side of the dielectric layer facing the package substrate, a second interposer metallization structure on another side of the dielectric layer facing the IC die, or a combination thereof.

Clause 26. The electronic device of clause 25, wherein: the first interposer metallization structure comprises at least one conductive pattern under the PMIC.

Clause 27. The electronic device of any of clauses 22 to 26, wherein: the interposer further comprises a capacitive device including a seventh power node and an eighth power node, the seventh power node is electrically coupled to the fourth power node and the fifth power node, and the eighth power node is electrically coupled to the second power node and the sixth power node.

Clause 28. The electronic device of any of clauses 22 to 27, wherein the IC comprises: based on the IC die at a face-up position with respect to the package substrate, a metallization portion facing the interposer, a device portion on the metallization portion, and a substrate portion on the device portion; or based on the IC die at a face-down position with respect to the package substrate, the substrate portion facing the interposer and including backside conductive structures formed therein, a device portion on the substrate portion, and a metallization portion on the device portion.

Clause 29. The electronic device of any of clauses 22 to 28, wherein a thickness of the interposer ranges from 30 micrometers (μm) to 60 μm.

Clause 30. The electronic device of any of clauses 22 to 29, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An integrated circuit (IC) package, comprising:
a package substrate including at least a first power node and a second power node;
an interposer on the package substrate, the interposer including:
a dielectric layer; and
a power management integrated circuit (PMIC) embedded in the dielectric layer, the PMIC including a third power node and a fourth power node, and the third power node being electrically coupled to the first power node; and
an IC die on the interposer, the IC die including a fifth power node and a sixth power node, the fifth power node being electrically coupled to the fourth power node, and the sixth power node being electrically coupled to the second power node,
wherein:
the first power node and the third power node are configured to carry a first supply voltage having a first voltage level,
the fourth power node and the fifth power node are configured to carry a second supply voltage having a second voltage level different from the first voltage level,
the second power node and the sixth power node are configured to carry a third supply voltage having a ground voltage level or a third voltage level different from the first voltage level and the second voltage level, and
the PMIC is configured to receive at the third power node the first supply voltage, and output at the fourth power node the second supply voltage.

2. The IC package of claim 1, wherein:
the PMIC is further configured to output at the fourth power node the second supply voltage based on the PMIC being at a power-on mode and to set the fourth power node at an open-circuit state based on the PMIC being at a power-off mode.

3. The IC package of claim 1, wherein:
the interposer further comprises one or more conductive structures, the dielectric layer surrounding the one or more conductive structures, and
the third power node is electrically coupled to the first power node through a first conductive structure of the one or more conductive structures.

4. The IC package of claim 1, wherein the interposer further comprises:
a first interposer metallization structure on one side of the dielectric layer facing the package substrate,
a second interposer metallization structure on another side of the dielectric layer facing the IC die, or
a combination thereof.

5. The IC package of claim 4, wherein:
the first interposer metallization structure comprises at least one conductive pattern under the PMIC.

6. The IC package of claim 1, wherein:
the interposer further comprises a capacitive device including a seventh power node and an eighth power node,
the seventh power node is electrically coupled to the fourth power node and the fifth power node, and
the eighth power node is electrically coupled to the second power node and the sixth power node.

7. The IC package of claim 6, wherein the capacitive device comprises:
a deep trench capacitor structure,
a metal-insulator-metal structure,
a metal-oxide-metal structure, or
a combination thereof.

8. The IC package of claim 1, wherein the IC die comprises:
based on the IC die at a face-up position with respect to the package substrate, a metallization portion facing the interposer, a device portion on the metallization portion, and a substrate portion on the device portion; or
based on the IC die at a face-down position with respect to the package substrate, the substrate portion facing the interposer and including backside conductive structures formed therein, a device portion on the substrate portion, and a metallization portion on the device portion.

9. The IC package of claim 8, wherein:
the third power node is electrically coupled to the first power node through a conductive pattern of the metallization portion of the IC die, a portion of the backside conductive structures, or a combination thereof.

10. The IC package of claim 1, wherein a thickness of the interposer ranges from 30 micrometers (μm) to 60 μm.

11. A method of manufacturing an integrated circuit (IC) package, comprising:
disposing an interposer on a package substrate, the package substrate including at least a first power node and a second power node, and the interposer including:
a dielectric layer; and
a power management integrated circuit (PMIC) embedded in the dielectric layer, the PMIC including a third power node and a fourth power node, and the third power node being electrically coupled to the first power node; and
disposing an IC die on the interposer, the IC die including a fifth power node and a sixth power node, the fifth power node being electrically coupled to the fourth power node, and the sixth power node being electrically coupled to the second power node,
wherein:
the first power node and the third power node are configured to carry a first supply voltage having a first voltage level,
the fourth power node and the fifth power node are configured to carry a second supply voltage having a second voltage level different from the first voltage level,
the second power node and the sixth power node are configured to carry a third supply voltage having a ground voltage level or a third voltage level different from the first voltage level and the second voltage level, and
the PMIC is configured to receive at the third power node the first supply voltage, and output at the fourth power node the second supply voltage.

12. The method of claim 11, further comprising forming the interposer, comprising:
disposing the PMIC on a carrier substrate;
forming one or more conductive structures on the carrier substrate;
forming the dielectric layer on the carrier substrate, the dielectric layer covering the PMIC and surrounding the one or more conductive structures; and
detaching the carrier substrate from the dielectric layer, the PMIC, and the one or more conductive structures.

13. The method of claim 11, wherein the disposing the IC die on the interposer is based on forming the interposer on a side of the IC die, comprising:
forming one or more conductive structures on the side of IC die;
disposing the PMIC on the side of the IC die;
forming the dielectric layer on the side of the IC die, the dielectric layer covering the PMIC and surrounding the one or more conductive structures; and
forming an interposer metallization structure on the dielectric layer such that the dielectric layer is between the interposer metallization structure and the IC die.

14. The method of claim 11, further comprising forming the interposer, comprising:
forming one or more conductive structures in the interposer, the dielectric layer surrounding the one or more conductive structures,
wherein the third power node is electrically coupled to the first power node through a first conductive structure of the one or more conductive structures.

15. The method of claim 11, further comprising forming the interposer, comprising:
forming a first interposer metallization structure on one side of the dielectric layer facing the package substrate,
forming a second interposer metallization structure on another side of the dielectric layer facing the IC die, or
a combination thereof.

16. The method of claim 11, further comprising forming the interposer, comprising:
disposing a capacitive device embedded in the dielectric layer, the capacitive device including a seventh power node and an eighth power node,
wherein:
the seventh power node is electrically coupled to the fourth power node and the fifth power node, and
the eighth power node is electrically coupled to the second power node and the sixth power node.

17. An electronic device, comprising:
an integrated circuit (IC) package that comprises:
a package substrate including at least a first power node and a second power node;
an interposer on the package substrate, the interposer including:
a dielectric layer; and
a power management integrated circuit (PMIC) embedded in the dielectric layer, the PMIC including a third power node and a fourth power node, and the third power node being electrically coupled to the first power node; and
an IC die on the interposer, the IC die including, a fifth power node and a sixth power node, the fifth power node being electrically coupled to the fourth power node, and the sixth power node being electrically coupled to the second power node,
wherein:
the first power node and the third power node are configured to carry a first supply voltage having a first voltage level,
the fourth power node and the fifth power node are configured to carry a second supply voltage having a second voltage level different from the first voltage level,
the second power node and the sixth power node are configured to carry a third supply voltage having a ground voltage level or a third voltage level different from the first voltage level and the second voltage level, and
the PMIC is configured to receive at the third power node the first supply voltage, and output at the fourth power node the second supply voltage.

18. The electronic device of claim 17, wherein:
the PMIC is further configured to output at the fourth power node the second supply voltage based on the PMIC being at a power-on mode and to set the fourth power node at an open-circuit state during based on the PMIC being at a power-off mode.

19. The electronic device of claim 17, wherein:
the interposer further comprises one or more conductive structures, the dielectric layer surrounding the one or more conductive structures, and
the third power node is electrically coupled to the first power node through a first conductive structure of the one or more conductive structures.

20. The electronic device of claim 17, wherein the interposer further comprises:
a first interposer metallization structure on one side of the dielectric layer facing the package substrate,
a second interposer metallization structure on another side of the dielectric layer facing the IC die, or
a combination thereof.
